(19) United States
(12) Patent Application Publication
(10) Pub. No.: US 2025/0287499 A1
(43) Pub. Date: Sep. 11, 2025

(54) PREPREG, LAMINATED PLATE, PRINTED WIRING BOARD, AND SEMICONDUCTOR PACKAGE

(71) Applicant: Resonac Corporation, Tokyo (JP)

(72) Inventors: Norihiko SAKAMOTO, Tokyo (JP); Kyousuke SUTOU, Tokyo (JP); Yoshiya SUNAIRI, Tokyo (JP); Shinji SHIMAOKA, Tokyo (JP)

(21) Appl. No.: 18/859,963

(22) PCT Filed: Oct. 4, 2023
(86) PCT No.: PCT/JP2023/036144

§ 371 Date: Oct. 24, 2024

(30) Foreign Application Priority Data
Oct. 12, 2022 (JP) 2022-164266

(51) Int. Cl. H05K 1/03; C08J 5/24

(52) U.S. Cl. CPC H05K 1/0366; C08J 5/244; C08J 5/249; C08J 2333/24; C08J 2363/00; H05K 2201/0195

(57) ABSTRACT

The present invention relates to a prepreg, which includes: a fiber base material; and a resin composition containing a thermosetting resin (A) and spherical zinc molybdate (B), in which the fiber base material has a basis weight of 50 g/m² or more, and a laminated plate, a printed wiring board, and a semiconductor package, each of which uses the prepreg.

### TECHNICAL FIELD

The present invention relates to a prepreg, a laminated plate, a printed wiring board, and a semiconductor package.

### BACKGROUND ART

In recent years, there has been an increasing demand for a printed wiring board used in electronic equipment, communication equipment, and the like to be smaller and lighter, and to have a higher wiring density and a faster calculation processing speed, and the like. Along with this, there is a growing demand for an insulating layer of a printed wiring board to have higher reliability than before.

As an insulating material for a printed wiring board, a prepreg obtained by impregnating a fiber base material such as a glass cloth with a resin composition is used. In a process for producing a printed wiring board, a cured product of a prepreg is sometimes subjected to hole drilling processing, but in particular when the fiber base material has a large basis weight, the hardness of the fiber base material may cause a deterioration in drilling processability such as a decrease in drilled hole positional accuracy.

Further, in recent years, in order to decrease the thermal expansion coefficient of an insulating layer, an inorganic filler is highly filled, or a harder fiber base material is used in some cases, and in such a case, the deterioration in drilling processability becomes more pronounced.

As a method for improving the drilling processability of a resin composition, a technique in which zinc molybdate is blended in the resin composition is known. PTL 1 discloses a resin composition containing a molybdenum compound supported on inorganic particles.

### CITATION LIST

### Patent Literature

PTL 1: JP 2019-199562 A

### SUMMARY OF INVENTION

### Technical Problem

However, according to the studies by the present inventors, it has been found that a prepreg formed using a resin composition containing a molybdenum compound supported on inorganic particles has poor adhesiveness to a copper foil (hereinafter also referred to as “copper foil adhesiveness”).

In view of such a current situation, an object of the present embodiment is to provide a prepreg having excellent drilling processability and copper foil adhesiveness, and a laminated plate, a printed wiring board, and a semiconductor package, each of which uses the prepreg.

### Solution to Problem

As a result of intensive studies to achieve the above object, the present inventors have found that the above object can be achieved by the present embodiment described below, and have completed the present embodiment.

That is, the present embodiment relates to the following [1] to [11].

[1] A prepreg, including; a fiber base material; and a resin composition containing a thermosetting resin (A) and spherical zinc molybdate (B), in which the fiber base material has a basis weight of 50 g/m² or more.

[2] The prepreg according to the above [1], in which the fiber base material has a thickness of 50 μm or more.

[3] The prepreg according to the above [1] or [2], in which the fiber base material is a glass cloth.

[4] The prepreg according to the above [3], in which a glass fiber constituting the glass cloth is one or more types selected from a group consisting of D-glass, T-glass, and S-glass.

[5] The prepreg according to any one of the above [1] to [4], in which the spherical zinc molybdate (B) has an average particle diameter (D50) of 0.01 to 20 μm.

[6] The prepreg according to any one of the above [1] to [5], in which a content of the spherical zinc molybdate (B) in the resin composition is 0.1 to 10% by mass with respect to a total solid content amount (100% by mass) of the resin composition.

[7] The prepreg according to any one of the above [1] to [6], in which the thermosetting resin (A) contains one or more types selected from a group consisting of a maleimide resin having one or more N-substituted maleimide groups and a derivative of the maleimide resin.

[8] The prepreg according to the above [7], in which the thermosetting resin (A) further contains an epoxy resin.

[9] A laminated plate, including: a cured product of the prepreg according to any one of the above [1] to [8]; and a metal foil.

[10] A printed wiring board, including a cured product of the prepreg according to any one of the above [1] to [8].

[11] A semiconductor package, including: the printed wiring board according to the above [10]; and a semiconductor element.

### Advantageous Effects of Invention

According to the present embodiment, it is possible to provide a prepreg having excellent drilling processability and copper foil adhesiveness, and a laminated plate, a printed wiring board, and a semiconductor package, each of which uses the prepreg.

### DESCRIPTION OF EMBODIMENTS

In the present description, a numerical range indicated using “to” indicates a range including the numerical values before and after “to” as the minimum value and the maximum value, respectively.

For example, the notation of a numerical range of “X to Y” (X and Y are real numbers) means a numerical range of X or more and Y or less. The description of “X or more” in the present description means X and a numerical value exceeding X. Further, the description of “Y or less” in the present description means Y and a numerical value less than Y.

The lower limit and the upper limit of a numerical range described in the present description can be arbitrarily combined with the lower limit and the upper limit of another numerical range, respectively.

In a numerical range described in the present description, the lower limit or the upper limit of the numerical range may be replaced with a value shown in Examples.

Unless otherwise specified, as each of the components and materials exemplified in the present description, one type may be used alone, or two or more types may be used in combination.

In the present description, when a plurality of substances corresponding to each component are present in the resin composition, the content of each component in the resin composition means the total amount of the plurality of substances present in the resin composition unless otherwise specified.

The “solid content” in the present description means components other than a solvent, and also includes components in a liquid state, a syrup-like state, and a waxy state at room temperature. Here, the room temperature in the present description refers to 25° C.

The expression of “containing XX” described in the present description includes both meanings: containing XX in a reacting state when XX can react; and simply containing XX. The weight average molecular weight (Mw) in the present description means a value measured in terms of polystyrene by gel permeation chromatography (GPC). Specifically, the weight average molecular weight (Mw) in the present description can be measured by the method described in Examples.

The “cured product” in the present description has the same meaning as a resin composition in the state of C-stage according to JIS K 6800 (2006).

The mechanism of action described in the present description is speculation and does not limit the mechanism that produces the effect of the present embodiment.

The present embodiment also includes embodiments in which matters described in the present description are arbitrarily combined.

### [Prepreg]

The prepreg of the present embodiment is a prepreg, which includes a fiber base material and a resin composition containing a thermosetting resin (A) and spherical zinc molybdate (B), and in which
the fiber base material has a basis weight of 50 g/m² or more.

Hereinafter, the components constituting the prepreg of the present embodiment, and the like will be described in order.

### [Resin Composition]

The prepreg of the present embodiment contains a resin composition containing a thermosetting resin (A) and spherical zinc molybdate (B).

### <(A) Thermosetting Resin>

Examples of the thermosetting resin (A) include an epoxy resin, a phenolic resin, a maleimide resin, a cyanate resin, an isocyanate resin, a benzoxazine resin, an oxetane resin, an amino resin, an unsaturated polyester resin, an allyl resin, a dicyclopentadiene resin, a silicone resin, a triazine resin, and a melamine resin.

As the thermosetting resin (A), one type may be used alone, or two or more types may be used in combination.

Among these, from the viewpoint of heat resistance and copper foil adhesiveness, the thermosetting resin (A) is preferably a maleimide resin, an epoxy resin, or a cyanate resin, and more preferably a maleimide resin or an epoxy resin.

### (Maleimide Resin)

The maleimide resin is preferably one or more types selected from the group consisting of a maleimide resin having one or more N-substituted maleimide groups and a derivative of the maleimide resin.

In the following description, “one or more types selected from the group consisting of a maleimide resin having one or more N-substituted maleimide groups and a derivative of the maleimide resin” are sometimes referred to as “maleimide-based resins”.

Further, in the following description, the maleimide resin having one or more N-substituted maleimide groups is sometimes referred to as “maleimide resin (AX)” or “component (AX)”.

Further, in the following description, the derivative of a maleimide resin having one or more N-substituted maleimide groups is sometimes referred to as “maleimide resin derivative (AY)” or “component (AY)”.

### —Maleimide Resin (AX)—

The maleimide resin (AX) is not particularly limited as long as being a maleimide resin having one or more N-substituted maleimide groups.

From the viewpoint of copper foil adhesiveness and heat resistance, the maleimide resin (AX) is preferably an aromatic maleimide resin having two or more N-substituted maleimide groups, and more preferably an aromatic bismaleimide resin having two N-substituted maleimide groups.

In the present description, the “aromatic maleimide resin” means a compound having an N-substituted maleimide group directly bonded to an aromatic ring.

Further, in the present description, the “aromatic bismaleimide resin” means a compound having two N-substituted maleimide groups directly bonded to an aromatic ring.

Further, in the present description, the “aromatic polymaleimide resin” means a compound having three or more N-substituted maleimide groups directly bonded to an aromatic ring.

Further, in the present description, the “aliphatic maleimide resin” means a compound having an N-substituted maleimide group directly bonded to an aliphatic hydrocarbon.

As the maleimide resin (AX), a maleimide resin represented by the following general formula (A1-1) [hereinafter referred to as “maleimide resin (A1)”] is preferred.

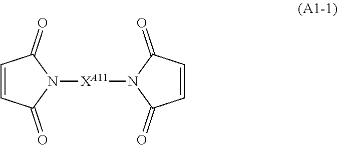

In the formula, X^{A11} is a divalent organic group.

X^{A11} in the general formula (A1-1) is a divalent organic group.

Examples of the divalent organic group represented by X^{A11} in the general formula (A1-1) include a divalent group represented by the following general formula (A1-2), a divalent group represented by the following general formula (A1-3), a divalent group represented by the following general formula (A1-4), a divalent group represented by the following general formula (A1-5), and a divalent group represented by the following general formula (A1-6).

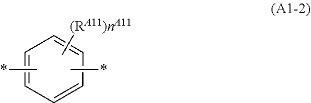

In the formula, R^{A11} is an aliphatic hydrocarbon group having 1 to 5 carbon atoms or a halogen atom, n^{A11} is an integer of 0 to 4, and * represents a binding site.

Examples of the aliphatic hydrocarbon group having 1 to 5 carbon atoms represented by R^{A11} in the general formula (A1-2) include an alkyl group having 1 to 5 carbon atoms such as a methyl group, an ethyl group, a n-propyl group, an isopropyl group, a n-butyl group, an isobutyl group, a t-butyl group, or a n-pentyl group; an alkenyl group having 2 to 5 carbon atoms; and an alkynyl group having 2 to 5 carbon atoms. The aliphatic hydrocarbon group having 1 to 5 carbon atoms may be either linear or branched.

Examples of the halogen atom include a fluorine atom, a chlorine atom, a bromine atom, and an iodine atom.

n^{A11} in the general formula (A1-2) is an integer of 0 to 4, and is preferably an integer of 0 to 2, more preferably 0 or 1, and still more preferably 0 from the viewpoint of availability.

When n^{A11} is an integer of 2 or more, a plurality of R^{A11}'s may be the same or different.

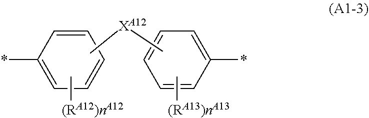

In the formula, R^{A12} and R^{A13} are each independently an aliphatic hydrocarbon group having 1 to 5 carbon atoms or a halogen atom, X^{A12} is an alkylene group having 1 to 5 carbon atoms, an alkylidene group having 2 to 5 carbon atoms, an ether group, a sulfide group, a sulfonyl group, a carbonyloxy group, a keto group, a single bond, or a divalent group represented by the following general formula (A1-3-1), n^{A12} and n^{A13} are each independently an integer of 0 to 4, and * represents a binding site.

Examples of the aliphatic hydrocarbon group having 1 to 5 carbon atoms represented by R^{A12} and R^{A13} in the general formula (A1-3) include an alkyl group having 1 to 5 carbon atoms such as a methyl group, an ethyl group, a n-propyl group, an isopropyl group, a n-butyl group, an isobutyl group, a t-butyl group, or a n-pentyl group; an alkenyl group having 2 to 5 carbon atoms; and an alkynyl group having 2 to 5 carbon atoms. The aliphatic hydrocarbon group having 1 to 5 carbon atoms may be either linear or branched. The aliphatic hydrocarbon group having 1 to 5 carbon atoms is preferably an aliphatic hydrocarbon group having 1 to 3 carbon atoms, more preferably an alkyl group having 1 to 3 carbon atoms, and still more preferably a methyl group or an ethyl group.

Examples of the halogen atom include a fluorine atom, a chlorine atom, a bromine atom, and an iodine atom.

Examples of the alkylene group having 1 to 5 carbon atoms represented by X^{A12} in the general formula (A1-3) include a methylene group, a 1,2-dimethylene group, a 1,3-trimethylene group, a 1,4-tetramethylene group, and a 1,5-pentamethylene group. The alkylene group having 1 to 5 carbon atoms is preferably an alkylene group having 1 to 3 carbon atoms, more preferably an alkylene group having 1 or 2 carbon atoms, and still more preferably a methylene group.

Examples of the alkylidene group having 2 to 5 carbon atoms represented by X^{A12} in the general formula (A1-3) include an ethylidene group, a propylidene group, an isopropylidene group, a butylidene group, an isobutylidene group, a pentylidene group, and an isopentylidene group. Among these, an alkylidene group having 2 to 4 carbon atoms is preferred, an alkylidene group having 2 or 3 carbon atoms is more preferred, and an isopropylidene group is still more preferred.

n^{A12} and n^{A13} in the general formula (A1-3) are each independently an integer of 0 to 4.

When n^{A12} or n^{A13} is an integer of 2 or more, a plurality of R^{A12}'s or a plurality of R^{A13}'s may be the same or different.

The divalent group represented by the general formula (A1-3-1) represented by X^{A12} in the general formula (A1-3) is as follows.

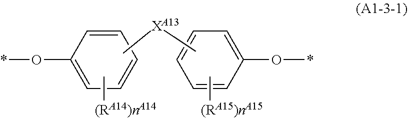

In the formula, R^{A14} and R^{A15} are each independently an aliphatic hydrocarbon group having 1 to 5 carbon atoms or a halogen atom, X^{A13} is an alkylene group having 1 to 5 carbon atoms, an alkylidene group having 2 to 5 carbon atoms, an ether group, a sulfide group, a sulfonyl group, a carbonyloxy group, a keto group, or a single bond, n^{A14} and n^{A15} are each independently an integer of 0 to 4, and * represents a binding site.

Examples of the aliphatic hydrocarbon group having 1 to 5 carbon atoms represented by R^{A14} and R^{A15} in the general formula (A1-3-1) include an alkyl group having 1 to 5 carbon atoms such as a methyl group, an ethyl group, a n-propyl group, an isopropyl group, a n-butyl group, an isobutyl group, a t-butyl group, or a n-pentyl group; an alkenyl group having 2 to 5 carbon atoms; and an alkynyl group having 2 to 5 carbon atoms. The aliphatic hydrocarbon group having 1 to 5 carbon atoms may be either linear or branched.

Examples of the halogen atom include a fluorine atom, a chlorine atom, a bromine atom, and an iodine atom.

Examples of the alkylene group having 1 to 5 carbon atoms represented by X^{A13} in the general formula (A1-3-1) include a methylene group, a 1,2-dimethylene group, a 1,3-trimethylene group, a 1,4-tetramethylene group, and a 1,5-pentamethylene group. The alkylene group having 1 to 5 carbon atoms is preferably an alkylene group having 1 to 3 carbon atoms, more preferably an alkylene group having 1 or 2 carbon atoms, and still more preferably a methylene group.

Examples of the alkylidene group having 2 to 5 carbon atoms represented by X^{A13} in the general formula (A1-3-1) include an ethylidene group, a propylidene group, an isopropylidene group, a butylidene group, an isobutylidene group, a pentylidene group, and an isopentylidene group. Among these, an alkylidene group having 2 to 4 carbon atoms is preferred, an alkylidene group having 2 or 3 carbon atoms is more preferred, and an isopropylidene group is still more preferred.

Among the above choices, X^{A13} in the general formula (A1-3-1) is preferably an alkylidene group having 2 to 5 carbon atoms, more preferably an alkylidene group having 2 to 4 carbon atoms, and still more preferably an isopropylidene group.

n^{A14} and n^{A15} in the general formula (A1-3-1) are each independently an integer of 0 to 4, and are each preferably an integer of 0 to 2, more preferably 0 or 1, and still more preferably 0 from the viewpoint of availability.

When n^{A14} or n^{A15} is an integer of 2 or more, a plurality of R^{A14}'s or a plurality of R^{A15}'s may be the same or different.

Among the above choices, X^{A12} in the general formula (A1-3) is preferably an alkylene group having 1 to 5 carbon atoms, an alkylidene group having 2 to 5 carbon atoms, or a divalent group represented by the general formula (A1-3-1), more preferably an alkylene group having 1 to 5 carbon atoms, and still more preferably a methylene group.

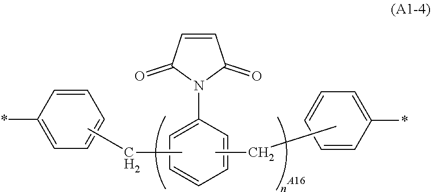

In the formula, n^{A16} is an integer of 0 to 10, and * represents a binding site.

n^{A16} in the general formula (A1-4) is preferably an integer of 0 to 5, more preferably an integer of 0 to 4, and still more preferably an integer of 0 to 3 from the viewpoint of availability.

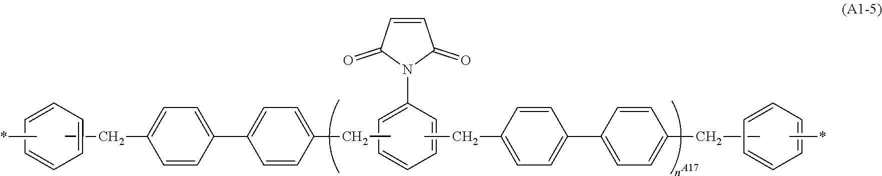

In the formula, n^{A17} is a number of 0 to 5, and * represents a binding site.

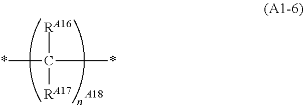

In the formula, R^{A16} and R^{A17} are each independently a hydrogen atom or an aliphatic hydrocarbon group having 1 to 5 carbon atoms, n^{A18} is an integer of 1 to 8, and * represents a binding site.

Examples of the aliphatic hydrocarbon group having 1 to 5 carbon atoms represented by R^{A16} and R^{A17} in the general formula (A1-6) include an alkyl group having 1 to 5 carbon atoms such as a methyl group, an ethyl group, a n-propyl group, an isopropyl group, a n-butyl group, an isobutyl group, a t-butyl group, or a n-pentyl group; an alkenyl group having 2 to 5 carbon atoms; and an alkynyl group having 2 to 5 carbon atoms. The aliphatic hydrocarbon group having 1 to 5 carbon atoms may be either linear or branched.

n^{A18} in the general formula (A1-6) is an integer of 1 to 8, and is preferably an integer of 1 to 5, more preferably an integer of 1 to 3, and still more preferably 1. When n^{A18} is an integer of 2 or more, a plurality of R^{A16}'s or a plurality of R^{A17}'s may be the same or different.

Examples of the maleimide resin (A1) include an aromatic bismaleimide resin, an aromatic polymaleimide resin, and an aliphatic maleimide resin.

Specific examples of the maleimide resin (A1) include N,N′-ethylenebismaleimide, N,N′-hexamethylenebismaleimide, N,N′-(1,3-phenylene)bismaleimide, N,N′-[1,3-(2-methylphenylene)]bismaleimide, N,N′-[1,3-(4-methylphenylene)]bismaleimide, N,N′-(1,4-phenylene)bismaleimide, bis(4-maleimidophenyl) methane, bis(3-methyl-4-maleimidophenyl) methane, 3,3′-dimethyl-5,5′-diethyl-4,4′-diphenylmethane bismaleimide, bis(4-maleimidophenyl) ether, bis(4-maleimidophenyl) sulfone, bis(4-maleimidophenyl) sulfide, bis(4-maleimidophenyl) ketone, bis(4-maleimidocyclohexyl) methane, 1,4-bis(4-maleimidophenyl)cyclohexane, 1,4-bis(maleimidomethyl)cyclohexane, 1,4-bis(maleimidomethyl)benzene, 1,3-bis(4-maleimidophenoxy)benzene, 1,3-bis(3-maleimidophenoxy)benzene, bis [4-(3-maleimidophenoxy)phenyl]methane, bis [4-(4-maleimidophenoxy)phenyl]methane, 1,1-bis [4-(3-maleimidophenoxy)phenyl]ethane, 1,1-bis [4-(4-maleimidophenoxy)phenyl]ethane, 1,2-bis [4-(3-maleimidophenoxy)phenyl]ethane, 1,2-bis [4-(4-maleimidophenoxy)phenyl]ethane, 2,2-bis [4-(3-maleimidophenoxy)phenyl]propane, 2,2-bis [4-(4-maleimidophenoxy)phenyl]propane, 2,2-bis [4-(3-maleimidophenoxy)phenyl]butane, 2,2-bis [4-(4-maleimidophenoxy)phenyl]butane, 2,2-bis [4-(3-maleimidophenoxy)phenyl]-1,1,1,3,3,3-hexafluoropropane, 2,2-bis [4-(4-maleimidophenoxy)phenyl]-1,1,1,3,3,3-hexafluoropropane, 4,4-bis(3-maleimidophenoxy) biphenyl, 4,4-bis(4-maleimidophenoxy) biphenyl, bis [4-(3-maleimidophenoxy)phenyl]ketone, bis [4-(4-maleimidophenoxy)phenyl]ketone, bis(4-maleimidophenyl)disulfide, bis [4-(3-maleimidophenoxy)phenyl]sulfide, bis [4-(4-maleimidophenoxy)phenyl]sulfide, bis [4-(3-maleimidophenoxy)phenyl]sulfoxide, bis [4-(4-maleimidophenoxy)phenyl]sulfoxide, bis [4-(3-maleimidophenoxy)phenyl]sulfone, bis [4-(4-maleimidophenoxy)phenyl]sulfone, bis [4-(3-maleimidophenoxy)phenyl]ether, bis [4-(4-maleimidophenoxy)phenyl]ether, 1,4-bis [4-(4-maleimidophenoxy)-α,α-dimethylbenzyl]benzene, 1,3-bis [4-(4-maleimidophenoxy)-α,α-dimethylbenzyl]benzene, 1,4-bis [4-(3-maleimidophenoxy)-α,α-dimethylbenzyl]benzene, 1,3-bis [4-(3-maleimidophenoxy)-α,α-dimethylbenzyl]benzene, 1,4-bis [4-(4-maleimidophenoxy)-3,5-dimethyl-α,α-dimethylbenzyl]benzene, 1,3-bis [4-(4-maleimidophenoxy)-3,5-dimethyl-α,α-dimethylbenzyl]benzene, 1,4-bis [4-(3-maleimidophenoxy)-3,5-dimethyl-α,α-dimethylbenzyl]benzene, 1,3-bis [4-(3-maleimidophenoxy)-3,5-dimethyl-α,α-dimethylbenzyl]benzene, polyphenylmethane maleimide, and biphenyl aralkyl type maleimide. Among these, 2,2-bis [4-(4-maleimidophenoxy)phenyl]propane is preferred.

### —Maleimide Resin Derivative (AY)—

The maleimide resin derivative (AY) is preferably a resin having a structure derived from the maleimide resin (AX) and a structure derived from a diamine compound [hereinafter sometimes referred to as “aminomaleimide resin (A2)” or “component (A2)”].

### —Aminomaleimide Resin (A2)—

The aminomaleimide resin (A2) has a structure derived from the maleimide resin (AX) and a structure derived from a diamine compound.

<Structure Derived from Maleimide Resin (AX)>

Examples of the structure derived from the maleimide resin (AX) include a structure formed by a Michael addition reaction between at least one N-substituted maleimide group among the N-substituted maleimide groups contained in the maleimide resin (AX) and an amino group contained in a diamine compound.

The structure derived from the maleimide resin (AX) contained in the aminomaleimide resin (A2) may be of one type alone or of two or more types.

The content of the structure derived from the maleimide resin (AX) in the aminomaleimide resin (A2) is not particularly limited, and is preferably 5 to 95% by mass, more preferably 30 to 93% by mass, and still more preferably 60 to 90% by mass.

When the content of the structure derived from the maleimide resin (AX) in the aminomaleimide resin (A2) is within the above range, the dielectric properties and handleability when a resin film is formed tend to become better.

<Structure Derived from Diamine Compound>

Examples of the structure derived from a diamine compound include a structure formed by a Michael addition reaction between one or both of the two amino groups contained in a diamine compound and an N-substituted maleimide group contained in the maleimide resin (AX).

The structure derived from a diamine compound contained in the aminomaleimide resin (A2) may be of one type alone or of two or more types.

The amino groups contained in a diamine compound are preferably primary amino groups.

Examples of the structure derived from a diamine compound having two primary amino groups include a group represented by the following general formula (A2-1) and a group represented by the following general formula (A2-2).

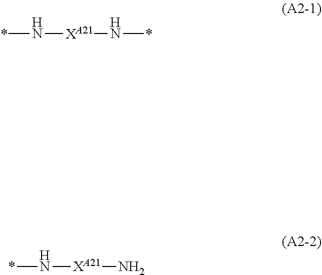

In the formula, X^{A21} is a divalent organic group, and * represents a binding site.

X^{A21} in the general formula (A2-1) and the general formula (A2-2) is a divalent organic group, and corresponds to a divalent group obtained by removing the two primary amino groups from the diamine compound.

X^{A21} in the general formula (A2-1) and the general formula (A2-2) is preferably a divalent group represented by the following general formula (A2-3).

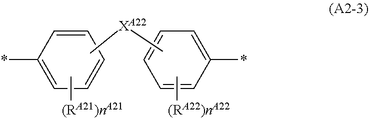

In the formula, R^{A21} and R^{A22} are each independently an aliphatic hydrocarbon group having 1 to 5 carbon atoms, an alkoxy group having 1 to 5 carbon atoms, a hydroxy group, or a halogen atom, X^{A22} is an alkylene group having 1 to 5 carbon atoms, an alkylidene group having 2 to 5 carbon atoms, an ether group, a sulfide group, a sulfonyl group, a carbonyloxy group, a keto group, a fluorenylene group, a single bond, or a divalent group represented by the following general formula (A2-3-1) or the following general formula (A2-3-2), n^{A21} and n A22 are each independently an integer of 0 to 4, and * represents a binding site.

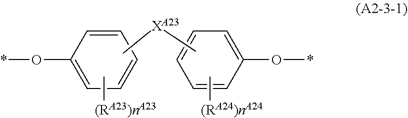

In the formula, R^{A23} and R^{A24} are each independently an aliphatic hydrocarbon group having 1 to 5 carbon atoms or a halogen atom, X^{A23} is an alkylene group having 1 to 5 carbon atoms, an alkylidene group having 2 to 5 carbon atoms, a m-phenylenediisopropylidene group, a p-phenylenediisopropylidene group, an ether group, a sulfide group, a sulfonyl group, a carbonyloxy group, a keto group, or a single bond, n^{A23} and n^{A24} are each independently an integer of 0 to 4, and * represents a binding site.

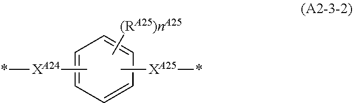

In the formula, R^{A25} is an aliphatic hydrocarbon group having 1 to 5 carbon atoms or a halogen atom, X^{A24} and X^{A25} are each independently an alkylene group having 1 to 5 carbon atoms, an alkylidene group having 2 to 5 carbon atoms, an ether group, a sulfide group, a sulfonyl group, a carbonyloxy group, a keto group, or a single bond, n^{A25} is an integer of 0 to 4, and * represents a binding site.

Examples of the aliphatic hydrocarbon group having 1 to 5 carbon atoms represented by R^{A21}, R^{A22}, R^{A23}, R^{A24}, and R^{A25} in the general formula (A2-3), the general formula (A2-3-1), and the general formula (A2-3-2) include an alkyl group having 1 to 5 carbon atoms such as a methyl group, an ethyl group, a n-propyl group, an isopropyl group, a n-butyl group, an isobutyl group, a t-butyl group, or a n-pentyl group; an alkenyl group having 2 to 5 carbon atoms; and an alkynyl group having 2 to 5 carbon atoms. The aliphatic hydrocarbon group having 1 to 5 carbon atoms may be either linear or branched. The aliphatic hydrocarbon group having 1 to 5 carbon atoms is preferably an aliphatic hydrocarbon group having 1 to 3 carbon atoms, more preferably an alkyl group having 1 to 3 carbon atoms, and still more preferably a methyl group or an ethyl group.

Examples of the halogen atom include a fluorine atom, a chlorine atom, a bromine atom, and an iodine atom.

Examples of the alkylene group having 1 to 5 carbon atoms represented by X^{A22} in the general formula (A2-3), X^{A23} in the general formula (A2-3-1), and X^{A24} and X^{A25} in the general formula (A2-3-2) include a methylene group, a 1,2-dimethylene group, a 1,3-trimethylene group, a 1,4-tetramethylene group, and a 1,5-pentamethylene group. The alkylene group having 1 to 5 carbon atoms is preferably an alkylene group having 1 to 3 carbon atoms, more preferably an alkylene group having 1 or 2 carbon atoms, and still more preferably a methylene group.

Examples of the alkylidene group having 2 to 5 carbon atoms represented by X^{A22} in the general formula (A2-3), X^{A23} in the general formula (A2-3-1), and X^{A24} and X^{A25} in the general formula (A2-3-2) include an ethylidene group, a propylidene group, an isopropylidene group, a butylidene group, an isobutylidene group, a pentylidene group, and an isopentylidene group. The alkylidene group having 2 to 5 carbon atoms is preferably an alkylidene group having 2 to 4 carbon atoms, more preferably an alkylidene group having 2 or 3 carbon atoms, and still more preferably an isopropylidene group.

n^{A21} and n^{A22} in the general formula (A2-3) are each independently an integer of 0 to 4, and are each preferably an integer of 0 to 3, more preferably an integer of 0 to 2, and still more preferably 0 or 2 from the viewpoint of availability.

When n^{A21} or n^{A22} is an integer of 2 or more, a plurality of R^{A21}'s or a plurality of R^{A22}'s may be the same or different.

n^{A23} and n^{A24} in the general formula (A2-3-1) are each independently an integer of 0 to 4, and are each preferably an integer of 0 to 2, more preferably 0 or 1, and still more preferably 0 from the viewpoint of availability.

When n^{A23} or n^{A24} is an integer of 2 or more, a plurality of R^{A23}'s or a plurality of R^{A24}'s may be the same or different.

n^{A25} in the general formula (A2-3-2) is an integer of 0 to 4, and is preferably an integer of 0 to 2, more preferably 0 or 1, and still more preferably 0 from the viewpoint of availability.

When n^{A25} is an integer of 2 or more, a plurality of R^{A25}'s may be the same or different.

Further, X^{A21} in the general formula (A2-1) and the general formula (A2-2) may be a divalent group containing a structure represented by the following general formula (A2-4), or may be a divalent group represented by the following general formula (A2-5).

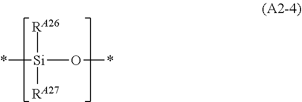

In the formula, R^{A26} and R^{A27} are each independently an aliphatic hydrocarbon group having 1 to 5 carbon atoms, a phenyl group, or a substituted phenyl group, and * represents a binding site.

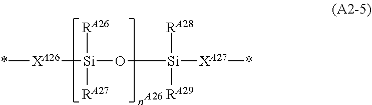

In the formula, R^{A26} and R^{A27} are the same as those in the general formula (A2-4), R^{A28} and R^{A29} are each independently an aliphatic hydrocarbon group having 1 to 5 carbon atoms, a phenyl group, or a substituted phenyl group, X^{A26} and X^{A27} are each independently a divalent organic group, n^{A26} is an integer of 2 to 100, and * represents a binding site.

Examples of the aliphatic hydrocarbon group having 1 to 5 carbon atoms represented by R^{A26} to R^{A29} in the general formulae (A2-4) and (A2-5) include an alkyl group having 1 to 5 carbon atoms such as a methyl group, an ethyl group, a n-propyl group, an isopropyl group, a n-butyl group, an isobutyl group, a t-butyl group, or a n-pentyl group; an alkenyl group having 2 to 5 carbon atoms; and an alkynyl group having 2 to 5 carbon atoms. The aliphatic hydrocarbon group having 1 to 5 carbon atoms may be either linear or branched. The aliphatic hydrocarbon group having 1 to 5 carbon atoms is preferably an aliphatic hydrocarbon group having 1 to 3 carbon atoms, more preferably an alkyl group having 1 to 3 carbon atoms, and still more preferably a methyl group.

Examples of the substituent contained in the phenyl group in the substituted phenyl group represented by R^{A26} to R^{A29} include the above-mentioned aliphatic hydrocarbon group having 1 to 5 carbon atoms.

Examples of the divalent organic group represented by X^{A26} and X^{A27} include an alkylene group, an alkenylene group, an alkynylene group, an arylene group, —O—, and a divalent linking group formed by combining these.

Examples of the alkylene group include an alkylene group having 1 to 10 carbon atoms such as a methylene group, an ethylene group, or a propylene group.

Examples of the alkenylene group include an alkenylene group having 2 to 10 carbon atoms.

Examples of the alkynylene group include an alkynylene group having 2 to 10 carbon atoms.

Examples of the arylene group include an arylene group having 6 to 20 carbon atoms such as a phenylene group or a naphthylene group.

Among these, X^{A26} and X^{A27} are preferably an alkylene group or an arylene group, and more preferably an alkylene group.

n^{A26} is an integer of 2 to 100, and is preferably an integer of 2 to 50, more preferably an integer of 3 to 40, and still more preferably an integer of 5 to 30. When n^{A26} is an integer of 2 or more, a plurality of R^{A26}'s or a plurality of R^{A27}'s may be the same or different.

The content of the structure derived from a diamine compound in the aminomaleimide resin (A2) is not particularly limited, and is preferably 5 to 95% by mass, more preferably 7 to 70% by mass, and still more preferably 10 to 40% by mass.

When the content of the structure derived from a diamine compound in the aminomaleimide resin (A2) is within the above range, the dielectric properties, heat resistance, flame retardancy, and glass transition temperature tend to become better.

Examples of the diamine compound include aromatic diamine compounds such as 4,4′-diaminodiphenylmethane, 3,3′-dimethyl-4,4′-diaminodiphenylmethane, 3,3′-diethyl-4,4′-diaminodiphenylmethane, 4,4′-diaminodiphenyl ether, 4,4′-diaminodiphenyl sulfone, 3,3′-diaminodiphenyl sulfone, 4,4′-diaminodiphenyl ketone, 4,4′-diaminobiphenyl, 3,3′-dimethyl-4,4′-diaminobiphenyl, 2,2′-dimethyl-4,4′-diaminobiphenyl, 3,3′-dihydroxybenzidine, 2,2-bis(3-amino-4-hydroxyphenyl) propane, 3,3′-dimethyl-5,5′-diethyl-4,4′-diaminodiphenylmethane, 2,2-bis(4-aminophenyl) propane, 2,2-bis [4-(4-aminophenoxy)phenyl]propane, 1,3-bis(3-aminophenoxy)benzene, 1,3-bis(4-aminophenoxy)benzene, 1,4-bis(4-aminophenoxy)benzene, 4,4′-bis(4-aminophenoxy) biphenyl, 1,3-bis [1-[4-(4-aminophenoxy)phenyl]-1-methylethyl]benzene, 1,4-bis [1-[4-(4-aminophenoxy)phenyl]-1-methylethyl]benzene, 4,4′-[1,3-phenylenebis(1-methylethylidene)]bisaniline 4,4′-[1,4-phenylenebis(1-methylethylidene)]bisaniline, 3,3′-[1,3-phenylenebis(1-methylethylidene)]bisaniline, bis [4-(4-aminophenoxy)phenyl]sulfone, bis [4-(3-aminophenoxy)phenyl]sulfone, and 9,9-bis(4-aminophenyl) fluorene; and silicone compounds having two primary amino groups.

In the present description, the “aromatic diamine compound” means a compound having two amino groups directly bonded to an aromatic ring.

Among these, from the viewpoint of excellent solubility in an organic solvent, reactivity, heat resistance, dielectric properties, and low water absorbability, the diamine compound is preferably 4,4′-diaminodiphenylmethane, 3,3′-dimethyl-4,4′-diaminodiphenylmethane, 3,3′-diethyl-4,4′-diaminodiphenylmethane, 2,2-bis [4-(4-aminophenoxy)phenyl]propane, 4,4′-[1,3-phenylenebis(1-methylethylidene)]bisaniline, and 4,4′-[1,4-phenylenebis(1-methylethylidene)]bisaniline, and more preferably 3,3′-diethyl-4,4′-diaminodiphenylmethane. Further, from the viewpoint of low thermal expandability, a silicone compound having two primary amino groups is preferred.

As the silicone compound having two primary amino groups, a silicone compound having primary amino groups at both ends is preferred.

The primary amino group equivalent of the silicone compound having two primary amino groups is not particularly limited, and is preferably 300 to 2,000 g/mol, more preferably 400 to 1,500 g/mol, and still more preferably 500 to 1,000 g/mol.

In the aminomaleimide resin (A2), the equivalent ratio (Ta2/Ta1) between the total equivalent (Ta2) of groups derived from the —NH₂ group of the diamine compound and the total equivalent (Ta1) of groups derived from the N-substituted maleimide group of the maleimide resin (AX) is not particularly limited, and is preferably 0.05 to 10, more preferably 1 to 8, and still more preferably 3 to 7 from the viewpoint of dielectric properties, heat resistance, flame retardancy, and glass transition temperature. Note that the groups derived from the —NH₂ group of the diamine compound shall also include —NH₂ itself. The groups derived from the N-substituted maleimide group of the maleimide resin (AX) shall also include the N-substituted maleimide group itself.

The weight average molecular weight (Mw) of the aminomaleimide resin (A2) is not particularly limited, and is preferably 400 to 10,000, more preferably 1,000 to 5,000, still more preferably 1,500 to 4,000, and particularly preferably 2,000 to 3,000 from the viewpoint of handleability and moldability.

The aminomaleimide resin (A2) can be produced, for example, by allowing the maleimide resin (AX) and the diamine compound to react with each other in an organic solvent.

By allowing the maleimide resin (AX) and the diamine compound to react with each other, the aminomaleimide resin (A2) is obtained through a Michael addition reaction between the maleimide resin (AX) and the diamine compound.

When the maleimide resin (AX) and the diamine compound are allowed to react with each other, a reaction catalyst may be used as needed.

The reaction temperature for the Michael addition reaction is preferably 50 to 160° C., more preferably 60 to 150° C., and still more preferably 70 to 140° C. from the viewpoint of workability such as a reaction rate, and prevention of gelation of the product during the reaction.

The reaction time for the Michael addition reaction is preferably 0.5 to 10 hours, more preferably 1 to 8 hours, and still more preferably 2 to 6 hours from the viewpoint of productivity and allowing the reaction to proceed sufficiently.

However, these reaction conditions can be appropriately adjusted depending on the types of raw materials to be used, or the like, and are not particularly limited.

### (Epoxy Resin)

The epoxy resin is preferably an epoxy resin having two or more epoxy groups.

Epoxy resins are classified into, for example, a glycidyl ether type epoxy resin, a glycidyl amine type epoxy resin, a glycidyl ester type epoxy resin, and the like. Among these, a glycidyl ether type epoxy resin is preferred.

Epoxy resins are also classified into various types of epoxy resins according to the difference in the main skeleton.

Specifically, the epoxy resins are classified into bisphenol type epoxy resins such as a bisphenol A type epoxy resin, a bisphenol F type epoxy resin, and a bisphenol S type epoxy resin; novolac type epoxy resins such as a bisphenol A novolac type epoxy resin, a bisphenol F novolac type epoxy resin, a phenol novolac type epoxy resin, a cresol novolac type epoxy resin, a biphenyl novolac type epoxy resin, and a naphthol novolac type epoxy resin; aralkyl type epoxy resins such as a phenol aralkyl type epoxy resin, a biphenyl aralkyl type epoxy resin, and a naphthol aralkyl type epoxy resin; a stilbene type epoxy resin; a naphthylene ether type epoxy resin; a biphenyl type epoxy resin; a dihydroanthracene type epoxy resin; an epoxy resin containing a saturated dicyclopentadiene skeleton; a cyclohexane dimethanol type epoxy resin; a spiro ring-containing epoxy resin; a heterocyclic epoxy resin; an alicyclic epoxy resin; an aliphatic chain epoxy resin; a rubber-modified epoxy resin; and the like. Among these, an epoxy resin containing a biphenyl structure is preferred, and a biphenyl aralkyl type epoxy resin is more preferred.

The resin composition of the present embodiment preferably contains, as the thermosetting resin (A), one or more types selected from the group consisting of a maleimide resin having one or more N-substituted maleimide groups and a derivative of the maleimide resin, and preferably further contains an epoxy resin.

The content of one or more types selected from the group consisting of a maleimide resin having one or more N-substituted maleimide groups and a derivative of the maleimide resin in the thermosetting resin (A) is not particularly limited, and is preferably 50 to 95% by mass, more preferably 60 to 90% by mass, and still more preferably 70 to 85% by mass.

The content of the epoxy resin in the thermosetting resin (A) is not particularly limited, and is preferably 5 to 50% by mass, more preferably 10 to 40% by mass, and still more preferably 15 to 30% by mass.

In the resin composition of the present embodiment, the content of the thermosetting resin (A) is not particularly limited, and is preferably 30 to 100% by mass, more preferably 50 to 100% by mass, and still more preferably 80 to 100% by mass with respect to the total amount (100% by mass) of the resin component in the resin composition of the present embodiment.

When the content of the thermosetting resin (A) is within the above range, the heat resistance, moldability, processability, and copper foil adhesiveness tend to easily become better.

In the present description, the “resin component” means a resin and a compound with which a resin is formed through a curing reaction. However, a curing accelerator (D) shall not be included in the resin component.

The content of the resin component in the resin composition of the present embodiment is not particularly limited, and is preferably 10 to 90% by mass, more preferably 20 to 70% by mass, and still more preferably 30 to 50% by mass with respect to the total solid content amount (100% by mass) of the resin composition of the present embodiment.

When the content of the resin component is equal to or more than the lower limit, the heat resistance, moldability, processability, and copper foil adhesiveness tend to easily become better. Further, when the content of the resin component is equal to or less than the upper limit, the low thermal expandability tends to easily become better.

### <Spherical Zinc Molybdate (B)>

The prepreg of the present embodiment is excellent not only in drilling processability but also in copper foil adhesiveness by containing the spherical zinc molybdate (B) in the resin composition. The reason why the prepreg of the present embodiment has excellent copper foil adhesiveness is not clear, but it is presumed that one of the reasons is that the spherical zinc molybdate (B) has an effect making the surface of the prepreg uniform, which improves the adhesion between the prepreg and the copper foil.

The zinc molybdate in the present embodiment is a salt of molybdic acid and zinc, and the composition formula thereof is represented by, for example, Zn_{X}Mo_{Y}O₄ (0.5<X<2.5, 0.5<Y<2.5), Zn_{X}Mo_{Y}O₄ (OH)_{Z} (0.5<X<2.5, 0.5<Y<2.5, 0.5<Z<2.5), or the like.

In the present embodiment, the “spherical” means that the circularity calculated by the following formula using the area and perimeter measured from a photograph of a target particle is 90 or more.

$$Circularity = \{ 4 π \times ( area ) \div {( perimeter )}^{2} \} \times 100$$

The closer the circularity is to 100, the closer it is to a perfect sphere, and the circularity of the spherical zinc molybdate (B) of the present embodiment is preferably 90 to 100, more preferably 93 to 100, and still more preferably 95 to 100 from the viewpoint of copper foil adhesiveness.

A more specific method for measuring the circularity is as described in Examples.

The average particle diameter (D₅₀) of the spherical zinc molybdate (B) is not particularly limited, and is preferably 0.01 to 20 μm, more preferably 0.1 to 10 μm, still more preferably 0.2 to 5 μm, and particularly preferably 0.5 to 1.5 μm from the viewpoint of copper foil adhesiveness.

In the present description, the average particle diameter (D₅₀) of particles refers to a particle diameter at a point corresponding to 50% volume when a cumulative frequency distribution curve of particle diameters is determined assuming that the total volume of the particles is 100%. The average particle diameter (D₅₀) can be measured, for example, by a particle size distribution measuring apparatus using a laser diffraction scattering method, or the like.

In the resin composition of the present embodiment, the content of the spherical zinc molybdate (B) is not particularly limited, and is preferably 0.1 to 10% by mass, more preferably 0.2 to 7% by mass, and still more preferably 0.5 to 5% by mass with respective to the total solid content amount (100% by mass) of the resin composition.

When the content of the spherical zinc molybdate (B) is within the above range, the drilling processability and copper foil adhesiveness tend to easily become better.

### <Inorganic Filler (C)>

The resin composition of the present embodiment preferably further contains an inorganic filler (C).

By containing the inorganic filler (C) in the resin composition of the present embodiment, more excellent low thermal expandability and heat resistance tend to be easily obtained.

In the present embodiment, the concept of the inorganic filler (C) shall not include the spherical zinc molybdate (B).

As the inorganic filler (C), one type may be used alone, or two or more types may be used in combination.

Examples of the inorganic filler (C) include silica, alumina, titanium oxide, mica, beryllia, barium titanate, potassium titanate, strontium titanate, calcium titanate, aluminum carbonate, magnesium hydroxide, aluminum hydroxide, aluminum silicate, calcium carbonate, calcium silicate, magnesium silicate, silicon nitride, boron nitride, clay, talc, aluminum borate, and silicon carbide. Among these, from the viewpoint of low thermal expandability, heat resistance, and flame retardancy, silica, alumina, mica, and talc are preferred, silica and alumina are more preferred, and silica is still more preferred.

Examples of the silica include precipitated silica which is produced by a wet method and has a high water content, and dry-method silica which is produced by a dry method and contains almost no bound water or the like. Examples of the dry-method silica include crushed silica, fumed silica, and fused silica according to the difference in production method. Among these, fused silica is preferred from the viewpoint of dispersibility and moldability.

The average particle diameter (D₅₀) of the inorganic filler (C) is not particularly limited, and is preferably 0.01 to 20 μm, more preferably 0.1 to 10 μm, still more preferably 0.2 to 5 μm, and particularly preferably 0.3 to 2 μm from the viewpoint of the dispersibility and fine wiring property of the inorganic filler (C).

Examples of the shape of the inorganic filler (C) include a spherical shape and a crushed shape, and a spherical shape is preferred.

In the resin composition of the present embodiment, a coupling agent may be used for the purpose of improving the dispersibility of the inorganic filler (C) and the adhesion between the inorganic filler (C) and an organic component. Examples of the coupling agent include a silane coupling agent and a titanate coupling agent. Among these, a silane coupling agent is preferred.

When the resin composition of the present embodiment contains the inorganic filler (C), the content of the inorganic filler (C) is not particularly limited, and is preferably 10 to 80% by mass, more preferably 30 to 75% by mass, still more preferably 40 to 70% by mass, even more preferably 50 to 67% by mass, and particularly preferably 55 to 65% by mass with respect to the total solid content amount (100% by mass) of the resin composition.

When the content of the inorganic filler (C) is equal to or more than the lower limit, the low thermal expandability and heat resistance tend to easily become better. Further, when the content of the inorganic filler (C) is equal to or less than the upper limit, the moldability and copper foil adhesiveness tend to easily become better.

### <Curing Accelerator (D)>

The resin composition of the present embodiment preferably further contains a curing accelerator (D).

By containing of the curing accelerator (D) in the resin composition of the present embodiment, the curability is improved, and more excellent copper foil adhesiveness tends to be easily obtained.

As the curing accelerator (D), one type may be used alone, or two or more types may be used in combination.

Examples of the curing accelerator (D) include acid catalysts such as p-toluenesulfonic acid; amine compounds such as triethylamine, tributylamine, pyridine, and dicyandiamide; imidazole compounds such as methylimidazole, phenylimidazole, 1-cyanoethyl-2-phenylimidazole, and 1-cyanoethyl-2-phenylimidazolium trimellitate; isocyanate-masked imidazole compounds such as an addition reaction product of a hexamethylene diisocyanate resin and 2-ethyl-4-methylimidazole; quaternary ammonium compounds; phosphorus-based compounds such as triphenylphosphine; organic peroxides such as dicumyl peroxide, 2,5-dimethyl-2,5-bis(t-butylperoxy) hexyne-3,2,5-dimethyl-2,5-bis(t-butylperoxy) hexane, t-butylperoxyisopropyl monocarbonate, and α,α′-bis(t-butylperoxy)diisopropylbenzene; and carboxylates of manganese, cobalt, zinc, and the like.

Among these, an isocyanate-masked imidazole compound is preferred from the viewpoint of a curing acceleration effect and storage stability.

When the resin composition of the present embodiment contains the curing accelerator (D), the content of the curing accelerator (D) is not particularly limited, and is preferably 0.01 to 10 parts by mass, more preferably 0.05 to 5 parts by mass, and still more preferably 0.1 to 1 part by mass with respective to 100 parts by mass of the thermosetting resin (A).

When the content of the curing accelerator (D) is equal to or more than the lower limit, a sufficient curing acceleration effect tends to be easily obtained. Further, when the content of the curing accelerator (D) is equal to or less than the upper limit, the storage stability tends to easily become better.

### <Other Optional Components>

The resin composition of the present embodiment may further contain, as necessary, one or more types of other optional components selected from the group consisting of a resin material other than the above-mentioned components, a flame retardant, an antioxidant, a heat stabilizer, an antistatic agent, a UV absorber, a pigment, a colorant, a lubricant, an organic solvent, and other additives.

As each of the optional components, one type may be used alone, or two or more types may be used in combination.

The content of the optional component in the resin composition of the present embodiment is not particularly limited, and the optional component may be used as needed within a range that does not impair the effect of the present embodiment.

Further, the resin composition of the present embodiment may not contain the optional component depending on the desired performance.

### (Organic Solvent)

The resin composition of the present embodiment may contain an organic solvent from the viewpoint of making the handling easier and making the production of a prepreg easier.

As the organic solvent, one type may be used alone, or two or more types may be used in combination.

In the present description, a resin composition containing an organic solvent is sometimes referred to as a resin varnish.

Examples of the organic solvent include alcohol-based solvents such as ethanol, propanol, butanol, methyl cellosolve, butyl cellosolve, and propylene glycol monomethyl ether; ketone-based solvents such as acetone, methyl ethyl ketone, methyl isobutyl ketone, and cyclohexanone; ether-based solvents such as tetrahydrofuran; aromatic hydrocarbon-based solvents such as toluene, xylene, and mesitylene; nitrogen atom-containing solvents such as dimethylformamide, dimethylacetamide, and N-methylpyrrolidone; sulfur atom-containing solvents such as dimethylsulfoxide; and ester-based solvents such as γ-butyrolactone.

Among these, from the viewpoint of solubility, an alcohol-based solvent, a ketone-based solvent, a nitrogen atom-containing solvent, and an aromatic hydrocarbon solvent are preferred, and an aromatic hydrocarbon solvent is more preferred, and toluene is still more preferred.

### <Method for Producing Resin Composition>

The resin composition of the present embodiment can be produced by mixing the respective components. At that time, the respective components may be dissolved or dispersed with stirring. The conditions such as mixing order, temperature, and time are not particularly limited and may be arbitrarily set depending on the type of raw material, and the like.

### [Fiber Base Material]

The fiber base material contained in the prepreg of the present embodiment has a basis weight of 50 g/m² or more.

When the fiber base material has a basis weight of 50 g/m² or more, the prepreg of the present embodiment has excellent mechanical strength.

The basis weight of the fiber base material is preferably 60 g/m² or more, more preferably 70 g/m² or more, and still more preferably 80 g/m² or more from the viewpoint of the mechanical strength of the prepreg, and is preferably 150 g/m² or less, more preferably 140 g/m² or less, still more preferably 130 g/m² or less, and particularly preferably 120 g/m² or less from the viewpoint of increasing the wiring density.

From the viewpoint of the mechanical strength of the prepreg and increasing the wiring density, the basis weight of the fiber base material is preferably 50 to 150 g/m², more preferably 60 to 140 g/m², still more preferably 70 to 130 g/m², and particularly preferably 80 to 120 g/m².

The thickness of the fiber base material is preferably 50 μm or more, more preferably 60 μm or more, still more preferably 70 μm or more, and particularly preferably 80 μm or more from the viewpoint of the mechanical strength of the prepreg, and is preferably 150 μm or less, more preferably 140 μm or less, still more preferably 130 μm or less, and particularly preferably 120 μm or less from the viewpoint of increasing the wiring density.

The thickness of the fiber base material is not particularly limited, and is preferably 50 to 150 μm, more preferably 60 to 140 μm, still more preferably 70 to 130 μm, and particularly preferably 80 to 120 μm from the viewpoint of the mechanical strength of the prepreg and increasing the wiring density.

The fiber base material may have the form of, for example, a woven fabric, a nonwoven fabric, a roving, a chopped strand mat, a surfacing mat, or the like.

From the viewpoint of the impregnation properties of the resin composition, or the like, the fiber base material may be surface-treated with a coupling agent, or may be subjected to a mechanical fiber spreading treatment.

Examples of the fiber constituting the fiber base material include inorganic fibers such as a glass fiber; organic fibers such as polyimide, polyester, tetrafluoroethylene, and the like; and mixtures thereof. Among these, from the viewpoint of low thermal expandability, an inorganic fiber is preferred, and a glass fiber is more preferred. From the same viewpoint, the fiber base material is preferably a glass cloth.

Examples of the glass fiber include E-glass, D-glass, T-glass, and S-glass. Among these, from the viewpoint of low thermal expandability, one or more types selected from the group consisting of D-glass, T-glass, and S-glass are preferred.

Representative compositions of E-glass, D-glass, T-glass, and S-glass are as follows.
E-glass: SiO₂ (52 to 56% by mass), Al₂O₃ (12 to 16% by mass), Fe₂O₃ (0 to 0.8% by mass), B203 (5 to 10% by mass), CaO (16 to 25% by mass), MgO (0 to 6% by mass), Na₂O+K₂O (0 to 2% by mass), TiO₂ (0 to 1.5% by mass), and F2 (0 to 1% by mass)
D-glass: SiO₂ (74% by mass), Al₂O₃ (0.5% by mass), B203 (22% by mass), CaO (0.5% by mass), NazO (1% by mass), K₂O (1.5% by mass), and LizO (0.5% by mass)
T-glass: SiO₂ (64 to 66% by mass), Al₂O₃ (24 to 26% by mass), and MgO (9 to 11% by mass)
S-glass: SiO₂ (62 to 65% by mass), Al₂O₃ (20 to 25% by mass), CaO (0 to 0.01% by mass), MgO (10 to 15% by mass), B203 (0 to 0.01% by mass), and Na₂O and K₂O (0 to 1% by mass)

The content of SiO₂ in the glass fiber is not particularly limited, and is preferably 30 to 95% by mass, more preferably 40 to 90% by mass, still more preferably 50 to 80% by mass, and particularly preferably 60 to 75% by mass.

When the content of SiO₂ in the glass fiber is equal to or more than the lower limit, the prepreg tends to have excellent low thermal expandability and low warpage properties. Further, when the content of SiO₂ in the glass fiber is equal to or less than the upper limit, the drilling processability of the prepreg tends to easily become better.

### [Method for Producing Prepreg]

The prepreg of the present embodiment can be produced, for example, by impregnating the fiber base material with the resin composition and then B-staging the resin composition.

As the method for impregnating the fiber base material with the resin composition, for example, a hot melt method, a solvent method, or the like can be adopted.

The hot melt method is a method in which the fiber base material is impregnated with the resin composition which does not contain an organic solvent.

One aspect of the hot melt method includes a method in which first, the resin composition of the present embodiment, which does not contain an organic solvent, is applied to a coated paper having good peelability, and then the applied resin composition is laminated on the fiber base material to impregnate the fiber base material.

Another aspect of the hot melt method includes a method in which the resin composition of the present embodiment, which does not contain an organic solvent, is directly applied to the fiber base material using a die coater or the like to impregnate the fiber base material.

The solvent method is a method in which the fiber base material is impregnated with the resin composition containing an organic solvent. Specific examples thereof include a method in which the fiber base material is immersed in the resin composition of the present embodiment containing an organic solvent, and then dried to remove the organic solvent and also to B-stage the resin composition.

The drying temperature is not particularly limited, and is preferably 50 to 200° C., more preferably 100 to 190° C., and still more preferably 150 to 180° C. from the viewpoint of productivity and appropriately B-staging the resin composition.

The drying time is not particularly limited, and is preferably 1 to 30 minutes, more preferably 2 to 15 minutes, and still more preferably 3 to 10 minutes from the viewpoint of productivity and appropriately B-staging the resin composition.

The content of the resin composition in the prepreg of the present embodiment is not particularly limited, and is preferably 30 to 80% by mass, more preferably 35 to 70% by mass, and still more preferably 40 to 60% by mass from the viewpoint of moldability.

### [Laminated Plate]

The laminated plate of the present embodiment is a laminated plate, which includes a cured product of the prepreg of the present embodiment and a metal foil.

The laminated plate including a metal foil is sometimes referred to as a metal-clad laminated plate.

The metal of the metal foil is not particularly limited, and examples thereof include copper, gold, silver, nickel, platinum, molybdenum, ruthenium, aluminum, tungsten, iron, titanium, chromium, and an alloy containing one or more of these metal elements.

The laminated plate of the present embodiment can be produced, for example, by placing a metal foil on one surface or both surfaces of the prepreg of the present embodiment, followed by hot-press molding.

Usually, the B-staged prepreg is cured by the hot-press molding to obtain the laminated plate of the present embodiment.

When the heat-press molding is performed, only one prepreg may be used, or two or more prepregs may be laminated and used.

For the hot-press molding, for example, a multi-stage press, a multi-stage vacuum press, continuous molding, an autoclave molding machine, or the like can be used.

The conditions for the hot-press molding are not particularly limited, and can be set to, for example, a temperature of 100 to 300° C., a time of 10 to 300 minutes, and a pressure of 1.5 to 5 MPa.

### [Printed Wiring Board]

The printed wiring board of the present embodiment is a printed wiring board, which includes a cured product of the prepreg of the present embodiment.

The printed wiring board of the present embodiment can be produced, for example, by forming a conductor circuit on the cured product of the prepreg of the present embodiment by a known method. In addition, a multilayer printed wiring board can also be produced by further performing multilayer bonding processing as needed. The conductor circuit can be formed, for example, by appropriately performing hole drilling processing, metal plating processing, etching processing of a metal foil, or the like.

### [Semiconductor Package]

The semiconductor package of the present embodiment is a semiconductor package, which includes the printed wiring board of the present embodiment and a semiconductor element.

The semiconductor package of the present embodiment can be produced, for example, by mounting a semiconductor chip, a memory, and the like on the printed wiring board of the present embodiment by a known method.

### EXAMPLES

The present embodiment will be specifically described below with reference to Examples. However, the present embodiment is not limited to the following Examples.

In each example, the weight average molecular weight (Mw) was measured by the following method.

The weight average molecular weight was calculated from a calibration curve using standard polystyrene by gel permeation chromatography (GPC). The calibration curve was approximated by a third order equation using standard polystyrene: TSK standard POLYSTYRENE (Type: A-2500, A-5000, F-1, F-2, F-4, F-10, F-20, and F-40) [trade name, manufactured by TOSOH CORPORATION]. The measurement conditions for GPC are shown below.

Apparatus:
Pump: L-6200 [manufactured by Hitachi High-Technologies Corporation]
Detector: L-3300 RI [manufactured by Hitachi High-Technologies Corporation]
Column oven: L-655A-52 [manufactured by Hitachi High-Technologies Corporation]
Column: Guard column: TSK Guardcolumn HHR-L+column: TSKgel G4000HHR+TSKgel G2000HHR (trade names, all manufactured by Tosoh Corporation)
Column size: 6.0×40 mm (guard column), 7.8× 300 mm (column)
Eluent: tetrahydrofuran
Sample concentration: 30 mg/5 mL
Injection volume: 20 μL
Flow rate: 1.00 mL/min
Measurement temperature: 40° C.

### Production Example 1: Production of Aminomaleimide Resin

In a heatable and coolable reaction vessel with a volume of 5 L equipped with a thermometer, a stirrer, and a moisture content meter with a reflux cooling tube, 100 parts by mass of 2,2-bis [4-(4-maleimidophenoxy)phenyl]propane, 5.6 parts by mass of a silicone compound (primary amino group equivalent: 750 g/mol) having primary amino groups at both ends, 7.9 parts by mass of 3,3′-diethyl-4,4′-diaminodiphenylmethane, and 171 parts by mass of propylene glycol monomethyl ether were placed, and a reaction was allowed to proceed under reflux for 2 hours. The mixture was concentrated at the reflux temperature for 3 hours to produce an aminomaleimide resin solution with a solid content concentration of 65% by mass. The weight average molecular weight (Mw) of the obtained aminomaleimide resin was about 2,700.

### [Method for Measuring Circularity]

Zinc molybdate was observed at a magnification of 5000x using a scanning electron microscope (SEM) (trade name “JSM-6010PLUS/LA”, manufactured by JEOL Ltd.), and the area and perimeter of any 10 particles in the obtained SEM photograph were measured. Subsequently, the circularity of each particle was calculated based on the following formula using the obtained area and perimeter, and the value obtained by averaging these was taken as the circularity of the zinc molybdate used in each example.

$$Circularity = \{ 4 π \times ( area ) \div {( perimeter )}^{2} \} \times 100$$

### Examples 1 and 2, and Comparative Examples 1 and 2

### (Production of Resin Composition)

The respective components shown in Table 1 were stirred and mixed with methyl ethyl ketone to prepare a varnish-like resin composition having a solid content concentration of 60% by mass. In Table 1, the unit of the blending amount of each component is parts by mass, and in the case of a solution, it means parts by mass in terms of solid content.

### (Production of Prepreg)

The varnish-like resin composition obtained above was impregnated into a glass cloth (basis weight: 114 g/m², type of glass: T-glass, thickness of glass cloth: 98 μm), followed by heating and drying at 120° C. for 3 minutes to obtain a prepreg. The content of the resin composition in the prepreg is 50% by mass.

### (Production of Copper-Clad Laminated Plate)

Seven prepregs obtained above were stacked, and a copper foil with a thickness of 12 μm (trade name “3EC-M3-VLP-12”, manufactured by Mitsui Kinzoku Co., Ltd., Rz of M surface (roughened surface): 3.0 μm) was placed on the top and bottom thereof so that the M surface (roughened surface) was in contact with the prepreg. The resulting laminate was subjected to heat-press molding for 90 minutes under the conditions of a temperature of 240° C. and a pressure of 3.0 MPa to obtain a copper-clad laminated plate.

### [Evaluation Method]

Each evaluation was performed according to the following method, and the results are shown in Table 1.

### (Method for Measuring Drilled Hole Positional Deviation Amount)

Three copper-clad laminated plates were stacked, and an aluminum foil with a thickness of 0.15 mm was placed thereon, and a paper phenolic plate with a thickness of 1.5 mm was placed underneath. Subsequently, 10,000 holes were opened using a drilling machine (trade name “ND-1V212”, manufactured by Via Mechanics, Ltd.) with a 0.15 mm drill under conditions of a rotation speed of 200 krpm, a feed rate of 2 m/min, and a chip load of 10 μm/rev. The positional deviation amount of holes on the lower side of the third plate (drill exit side) of the stacked three copper-clad laminated plates was measured using a hole positional accuracy meter (trade name “HT-1AM”, manufactured by Via Mechanics, Ltd.), and the average of the positional deviation amount of 10,000 holes+36 (o: standard deviation) was calculated and used as an index of drilled hole positional accuracy.

### (Method for Measuring Copper Foil Peel Strength)

The copper foil of the copper-clad laminated plate prepared above was processed in a straight line shape with a width of 5 mm by etching to prepare a test piece. The straight line-shaped copper foil thus formed was attached to a small tabletop tester (trade name “EZ-TEST”, manufactured by Shimadzu Corporation) and peeled off in a direction of 90° at room temperature (25° C.) to measure the copper foil peel strength. The pulling speed when the copper foil was peeled off was set to 50 mm/min.

TABLE 1

| | | | | | Comparative | |
|---|---|---|---|---|---|---|
| | | | Example | | Example | |
| | | | 1 | 2 | 1 | 2 |
| Blending | Component | Thermosetting resin 1 | 80.0 | 80.0 | 80.0 | 80.0 |
| composition | (A) | Thermosetting resin 2 | 20.0 | 20.0 | 20.0 | 20.0 |
| (parts | Component | Spherical zinc molybdate | 1.0 | 5.0 | | |
| by mass) | (B) | | | | | |
| | Comparative | Zinc molybdate- | | | | 25.0 |
| | component | supported talc | | | | |
| | Component | Fused silica | 149.0 | 145.0 | 150.0 | 125.0 |
| | (C) | | | | | |
| | Component | Curing accelerator | 0.5 | 0.5 | 0.5 | 0.5 |
| | (D) | | | | | |

| | | | | | |
|---|---|---|---|---|---|
| Evaluation | Drilled hole positional deviation amount | 80 | 20 | 120 | 20 |
| results | (average + 3σ) (μm) | | | | |
| | Copper foil peel strength (kN/m) | 0.6 | 0.6 | 0.6 | 0.2 |

The details of the respective components shown in Table 1 are as follows.

### [Component (A)]

Thermosetting resin 1: Aminomaleimide resin prepared in Production Example 1

Thermosetting resin 2: Biphenyl aralkyl type epoxy resin, “NC-3000” manufactured by Nippon Kayaku Co., Ltd., epoxy equivalent: 275 g/eq

### [Component (B)]

Spherical zinc molybdate: average particle diameter (D₅₀): 0.9 μm, circularity: 99

[Comparative component]

Zinc molybdate-supported talc: flaky, circularity: less than 90, supported amount of zinc molybdate: 20% by mass

### [Component (C)]

Fused silica: average particle diameter (D₅₀): 0.5 μm, spherical fused silica

### [Component (D)]

Curing accelerator: isocyanate-masked imidazole, trade name “G-8009L”, manufactured by DKS Co. Ltd.

From Table 1, it can be seen that the prepregs of Examples 1 and 2 of the present embodiment can reduce the drilled hole positional deviation amount while maintaining the copper foil peel strength as compared with the prepreg of Comparative Example 1 obtained without adding the spherical zinc molybdate (B). On the other hand, the prepreg of Comparative Example 2 obtained by adding zinc molybdate-supported talc, which is not the spherical zinc molybdate (B), can reduce the drilled hole positional deviation amount, but the copper foil peel strength was significantly reduced.

1. A prepreg, comprising:
a fiber base material; and
a resin composition containing a thermosetting resin (A) and spherical zinc molybdate (B), wherein
the fiber base material has a basis weight of 50 g/m² or more.

2. The prepreg according to claim 1, wherein the fiber base material has a thickness of 50 μm or more.

3. The prepreg according to claim 1, wherein the fiber base material is a glass cloth.

4. The prepreg according to claim 3, wherein a glass fiber constituting the glass cloth is one or more types selected from a group consisting of D-glass, T-glass, and S-glass.

5. The prepreg according to claim 1, wherein the spherical zinc molybdate (B) has an average particle diameter (D₅₀) of 0.01 to 20 μm.

6. The prepreg according to claim 1, wherein a content of the spherical zinc molybdate (B) in the resin composition is 0.1 to 10% by mass with respect to a total solid content amount (100% by mass) of the resin composition.

7. The prepreg according to claim 1, wherein the thermosetting resin (A) contains one or more types selected from a group consisting of a maleimide resin having one or more N-substituted maleimide groups and a derivative of the maleimide resin.

8. The prepreg according to claim 7, wherein the thermosetting resin (A) further contains an epoxy resin.

9. A laminated plate, comprising: a cured product of the prepreg according to claim 1; and a metal foil.

10. A printed wiring board, comprising a cured product of the prepreg according to claim 1.

11. A semiconductor package, comprising:
the printed wiring board according to claim 10; and
a semiconductor element.
